(19) United States
(12) Patent Application Publication
(10) Pub. No.: US 2014/0083976 A1
(43) Pub. Date: Mar. 27, 2014

(54) CLUSTER BEAM GENERATING APPARATUS, SUBSTRATE PROCESSING APPARATUS, CLUSTER BEAM GENERATING METHOD, AND SUBSTRATE PROCESSING METHOD

(71) Applicants: Tokyo Electron Limited, Tokyo (JP); HYOGO PREFECTURE, Hyogo (JP)

(72) Inventors: Noriaki TOYODA, Hyogo (JP); Isao YAMADA, Hyogo (JP); Masaki NARUSHIMA, Yamanashi (JP)

(73) Assignees: Tokyo Electron Limited, Tokyo (JP); HYOGO PREFECTURE, Hyogo (JP)

(21) Appl. No.: 14/093,058

(22) Filed: Nov. 29, 2013

Related U.S. Application Data
(62) Division of application No. 13/113,746, filed on May 23, 2011.

(30) Foreign Application Priority Data
May 26, 2010 (JP) 2010-120919

(51) Int. Cl. H01J 37/08

(52) U.S. Cl. CPC H01J 37/08
USPC 216/66; 250/424; 134/1.1

(57) ABSTRACT

A cluster beam generating method that generates a cluster beam includes steps of mixing a gas source material and a liquid source material in a mixer; supplying a cluster beam including clusters originating from the gas source material and clusters originating from the liquid source material that are mixed in the mixer from a nozzle; and adjusting a temperature of the nozzle using a temperature adjusting portion that adjusts a temperature of the nozzle, thereby controlling a ratio of the clusters originating from the gas source material and the clusters originating from the liquid source material in the cluster beam.

### CROSS-REFERENCE TO RELATED APPLICATIONS

The present application is a divisional application of U.S. patent application Ser. No. 13/113,746 filed May 23, 2011, which claims priority under 35 U.S.C. §119 to Japanese Priority Application No. 2010-120919 filed May 26, 2010, the entire contents of which are hereby incorporated herein by reference.

### BACKGROUND OF THE INVENTION

1. Field of the Invention

The present invention relates to a cluster beam generating apparatus, a substrate processing apparatus, cluster beam generating method, and a substrate processing method.

2. Description of the Related Art

Gas clusters into which a plurality of atoms and the like are condensed exhibit a unique physicochemical behavior, and attract attention for applications in various fields of technologies. Namely, gas cluster ion beams are thought to be applicable for processes such as ion-implantation, surface machining, and thin film deposition in a depth range of several nanometers from a surface of a solid material, while the processes in such a depth range have been considered difficult with conventional technologies.

In a gas cluster generating apparatus, it is possible to generate gas clusters formed of several hundred through several thousand atoms from a compressed gas supplied from a gas supplying source. The number of the atoms in the gas cluster generated by the gas cluster generating apparatus is stochastically-distributed, and thus the gas clusters range in mass.

In addition, in the gas cluster generating apparatus, it may be required to generate clusters from not only a gas source but also a liquid source. A patent document (Japanese Patent Application Laid-Open Publication No. H09-143700) discloses a cluster ion beam apparatus that generates clusters from a liquid material that is in the liquid phase at room temperature.

Incidentally, when a substrate or the like is processed using clusters originating from a liquid, a mix ratio of the clusters originating from a liquid and those from a gas needs to be rapidly changed, if necessary. In this case, it takes a relatively long time to stabilize the mix ratio of the clusters originating from a liquid and those from a gas, if a mass flow controller or the like is used to change the mix ratio of the clusters originating from a liquid and a gas. In addition, the liquid and the gas source materials may be wasted before the mix ratio is stabilized.

On the other hand, it is advisable to use a single cluster beam generating apparatus in order to carry out a plurality of processes using clusters originating from the gas source and clusters originating from the liquid source, because the plurality of processes can be carried out in a single chamber, thereby improving process throughput and suppressing contamination of the substrate.

The present invention has been made in view of the above, and provides a cluster beam generating apparatus and a substrate processing apparatus that are capable of rapidly changing a mix ratio of clusters originating from liquid and gas sources, and a cluster beam generating method and a substrate processing method that are capable of carrying out a plurality of processes employing the cluster beam generating apparatus and the substrate processing apparatus, respectively.

### SUMMARY OF THE INVENTION

According to a first aspect of the present invention, there is provided a cluster beam generating apparatus that generates a cluster beam. This cluster beam generating apparatus includes a mixer that mixes a gas source material and a liquid source material; a nozzle that supplies a cluster beam including clusters originating from the gas source material and the liquid source material that are mixed in the mixer; and a temperature adjusting portion that adjusts a temperature of the nozzle, thereby controlling a ratio of the clusters originating from the gas source material and the clusters originating from the liquid source material in the cluster beam.

According to a second aspect of the present invention, there is provided a substrate processing apparatus comprising the cluster beam generating apparatus according to the first aspect, thereby carrying out a substrate process by irradiating the cluster beam generated by the cluster beam generating apparatus.

According to a third aspect of the present invention, there is provided a cluster beam generating method that generates a cluster beam. The cluster beam generating method includes steps of: mixing a gas source material and a liquid source material in a mixer; supplying a cluster beam including clusters originating from the gas source material and the liquid source material that are mixed in the mixer from a nozzle; and adjusting a temperature of the nozzle using a temperature adjusting portion that adjusts a temperature of the nozzle, thereby controlling a ratio of the clusters originating from the gas source material and the clusters originating from the liquid source material in the cluster beam.

According to a fourth aspect of the present invention, there is provided a substrate processing method comprising a step of irradiating a cluster beam generated by the cluster beam generating method according to the third aspect onto a substrate, thereby carrying out a substrate process with respect to the substrate.

### BRIEF DESCRIPTION OF THE DRAWINGS

FIG. 1 is a schematic view of a cluster beam generating apparatus and a substrate processing apparatus according to a first embodiment;

FIG. 2 is a schematic view of a source material supplying portion of the apparatus of FIG. 1;

FIG. 3 illustrates quadrupole mass spectrometry spectra with a temperature of a nozzle of the apparatus of FIG. 1 as a parameter;

FIG. 4 illustrates the partial pressures of clusters generated by the apparatus of FIG. 1 as a function of a temperature of the nozzle;

FIG. 5 illustrates a partial pressure of methanol as a function of a temperature of the nozzle;

FIG. 6 illustrates an average particle size of the clusters as a function of a temperature of the nozzle.

FIG. 7 is a flowchart illustrating a substrate processing method according to a second embodiment.

### DETAILED DESCRIPTION OF THE PREFERRED EMBODIMENT

According to an embodiment of the present invention, there are provided a cluster beam generating apparatus and a substrate processing apparatus that are capable of rapidly changing a mix ratio of clusters originating from liquid and gas sources, and a cluster beam generating method and a substrate processing method that are capable of carrying out a plurality of processes employing the cluster beam generating apparatus and the substrate processing apparatus, respectively.

### First Embodiment

A cluster beam generating apparatus and a substrate processing apparatus according to a first embodiment are explained. The cluster beam generating apparatus according to this embodiment is capable of generating clusters from a gas source that is in the gas phase at room temperature (simply referred to as gas source, hereinafter) and a liquid source that is in the liquid phase at room temperature (simply referred to as liquid source, hereinafter), and is capable of easily changing a ratio of the clusters from the gas source and those from the liquid source. In addition, the substrate processing apparatus according to this embodiment is configured to process a substrate employing the cluster beam generating apparatus according to this embodiment.

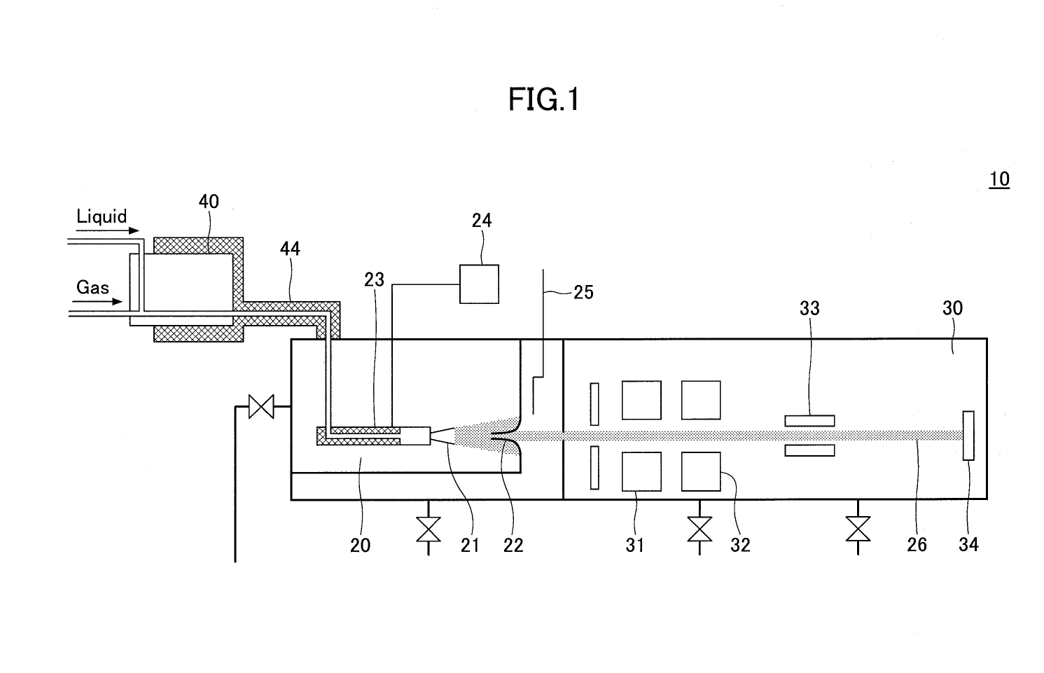

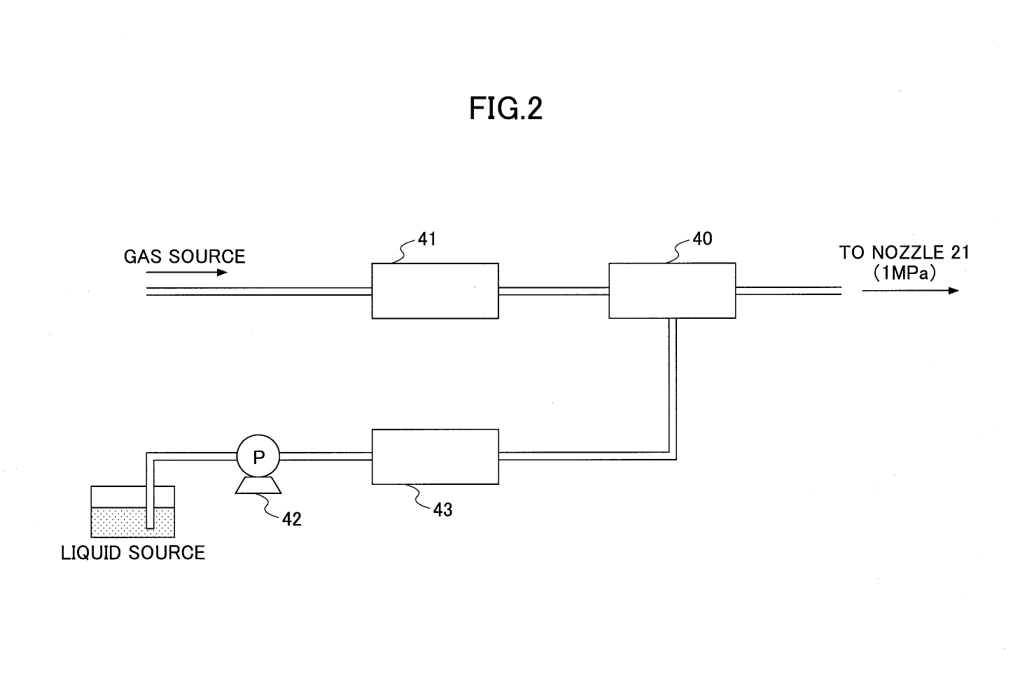

First, a cluster ion beam generating apparatus as the cluster beam generating apparatus and the substrate processing apparatus according to a first embodiment is explained with reference to FIG. 1 and FIG. 2.

As shown in FIG. 1, a cluster ion beam generating apparatus 10 includes a nozzle chamber 20 and a main chamber 30. The nozzle chamber 20 is provided with a nozzle 21 that generates clusters and a skimmer 22 that separates the generated clusters. The clusters that have passed through the skimmer 22 are introduced into the main chamber 30. The main chamber 30 is provided with an ionizing portion 31 that ionizes the clusters. The ionized clusters are accelerated by an accelerating portion 32, separated by an electrode portion 33, and irradiated onto a substrate 34, so that the substrate 34 is processed by a cluster beam 26 irradiated thereon. The nozzle 21 is provided with a temperature adjusting portion 23 that can control a temperature, such as a heater. The temperature adjusting portion 23 is controlled by a temperature controlling portion 24, thereby adjusting a temperature. In addition, a liquid source and a gas source that are source materials of the cluster beam 26 are mixed in a mixer 40, and the mixed sources are supplied to the nozzle 21. Incidentally, a shutter 25 is provided between the nozzle chamber 20 and the main chamber 30, and introduction of the cluster beam 26 into the main chamber 30 is controlled by opening/closing the shutter 25.

As shown in FIG. 2, the gas source is supplied to the mixer 40 through a mass flow controller 41, and the liquid source is supplied to the mixer 40 through a pump 42 and a liquid mass flow controller 43. In this embodiment, argon (Ar) gas is used as the gas source and methanol (CH₃OH) is used as the liquid source. The Ar gas is flow-controlled at a flow rate of 200 sccm by the mass flow controller 41 and supplied to the mixer 40. The methanol is flow-controlled at a flow rate of 0.02 sccm by the liquid mass flow controller 43 and supplied to the mixer 40. As shown in FIG. 1, the mixer 40 is provided with a heater 44, and heated up to a predetermined temperature, so that the methanol is vaporized in the mixer 40. The Ar gas and the vaporized methanol are supplied to the nozzle 21.

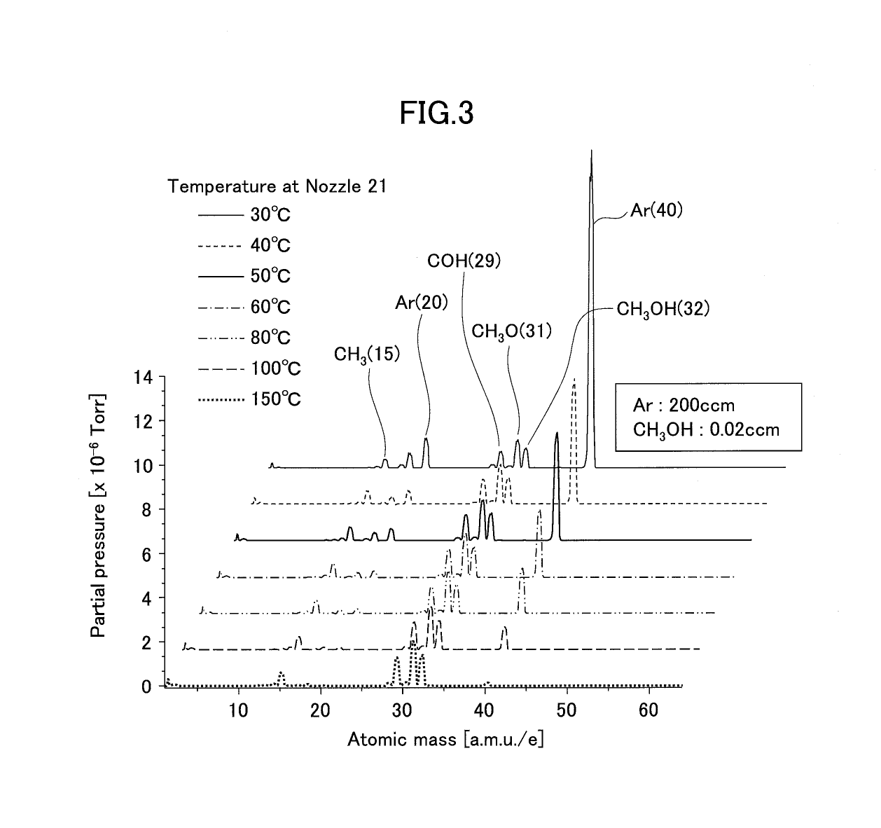

FIG. 3 illustrates how a ratio of Ar clusters and methanol clusters in the cluster beam 26 is changed by the temperature of the temperature adjusting portion 23. The graph in FIG. 3 is obtained through quadrupole mass spectrometry. Namely, a quadrupole mass spectrometer (not shown) is provided in the main chamber 30 and the Ar clusters and methanol clusters are measured with the quadrupole mass spectrometer by changing the temperature of the temperature adjusting portion 23, namely the nozzle 21, while the heater 44 provided in the mixer 40 is set to 150° C. As shown, when a temperature of the temperature adjusting portion 23 is set to 30° C., an extremely large amount of the Ar clusters is observed while only a small amount of the methanol clusters is observed in the main chamber 30. However, as the temperature of the temperature adjusting portion 23 is raised, the amount of the Ar clusters is rapidly decreased and thus the amount of the methanol clusters is increased relative to the amount of the Ar clusters. Therefore, the ratio of the Ar clusters and the methanol clusters can be changed by the changing the temperature of the temperature adjusting portion 23, namely the nozzle 21.

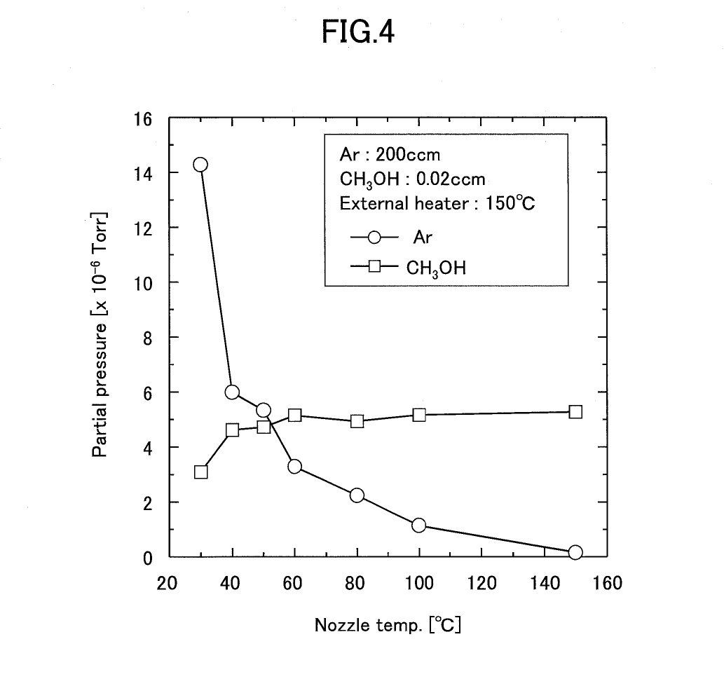

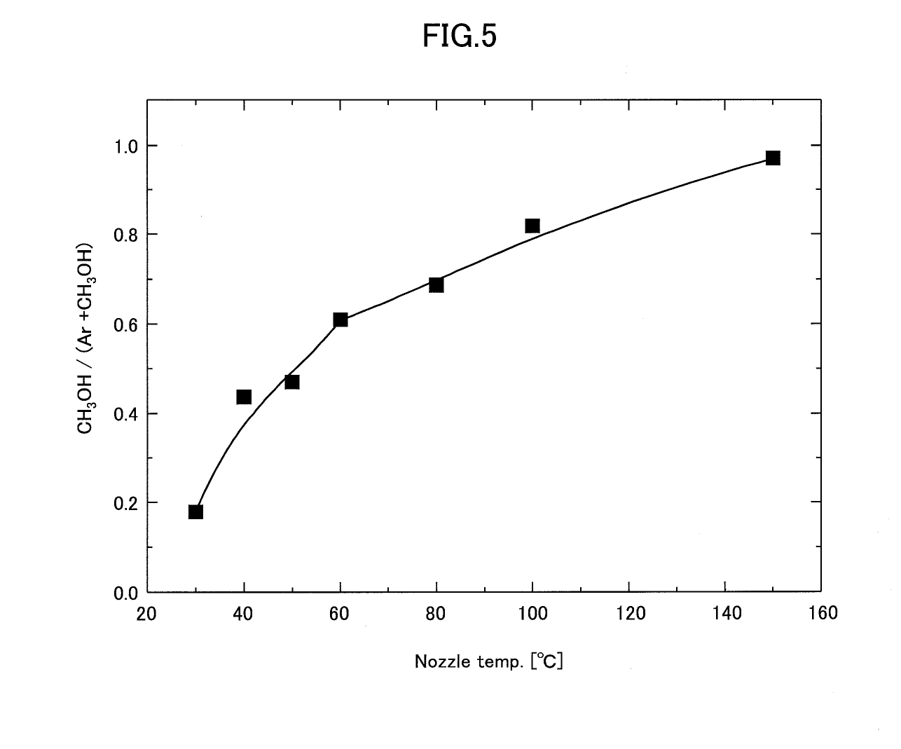

FIG. 4 illustrates partial pressures of Ar and methanol in the clusters (cluster beam 26) in relation to the temperature of the nozzle 21, and FIG. 5 illustrates a partial pressure ratio of the methanol clusters in relation to the temperature of the nozzle 21. As shown in FIGS. 4 and 5, the pressure ratio of the methanol clusters can be adjusted by changing the temperature of the temperature adjusting portion 23, namely the temperature of the nozzle 21.

Therefore, the partial pressure of the methanol clusters can be rapidly adjusted by changing only the temperature of the nozzle 21. Namely, if the partial pressure of the methanol clusters is controlled by controlling flow rates of the Ar and the methanol, because a distance between the mass flow controllers 41, 43 and the nozzle 21 is relatively large, it takes a relatively long time to set the partial pressure of the methanol clusters to a desired partial pressure in the main chamber 30, and the source materials supplied until the desired partial pressure is realized goes to waste. However, because the partial pressure of the methanol clusters can be controlled by controlling the temperature of the nozzle 21 in the cluster ion beam generating apparatus, the desired partial pressure of the methanol clusters is realized in a short period of time, and an amount of the waste source materials can be reduced. Therefore, throughputs in the substrate processing can be improved, and a cost of the substrate processing can be reduced.

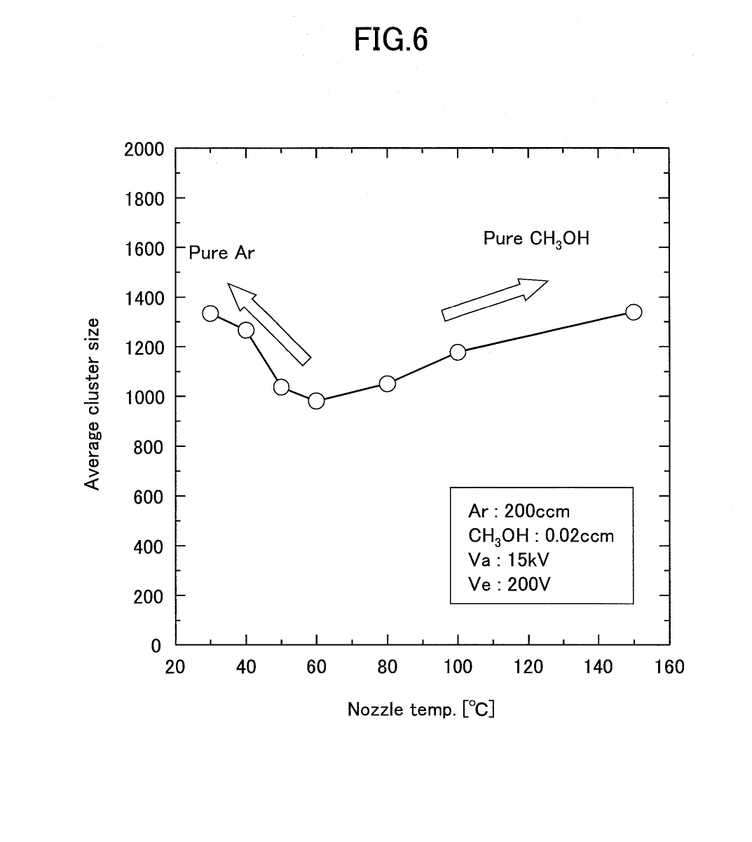

Next, a relationship between an average size of the clusters and the temperature of the nozzle 21 is explained with reference to FIG. 6. As shown, sizes of the clusters supplied from the nozzle 21 are within a range of about 1000 through about 1400 atoms/cluster even when the temperature of the temperature adjusting portion 23, namely the nozzle 21, is changed in the cluster ion beam generating apparatus according to this embodiment. In other words, the cluster ion beam generating apparatus according to this embodiment can generate the clusters having substantially the same average size regardless of the temperature of the nozzle 21. Therefore, the partial pressure of the methanol clusters or the Ar clusters can be changed without changing the sizes of the clusters.

Incidentally, although the cluster ion beam generating apparatus that generates ionized clusters has been explained in the above embodiment, a cluster beam generating apparatus that generates neutral clusters can be configured by removing the ionization portion 31, the accelerating portion 32, and the electrode portion 33 from the cluster ion beam generating apparatus 10 shown in FIG. 10.

The cluster beam generating apparatus according to this embodiment may be provided with a plurality of the nozzles 21 having different temperatures. In this case, the nozzles 21 may be selected and used depending on the temperature suitable for an intended use.

In addition, although the Ar gas as the gas source and the methanol as the liquid source are used in the above embodiment, any source materials can be used as long as one is in the gas phase at room temperature and another is in the liquid phase at room temperature.

### Second Embodiment

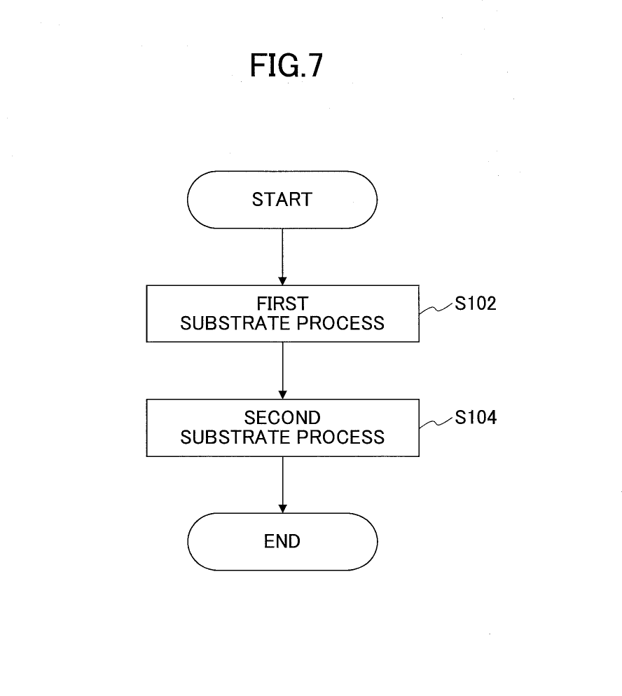

Next, referring to FIG. 7, a substrate processing method according to a second embodiment of the present invention is explained by taking as an example a case where the cluster ion beam generating apparatus and the substrate processing apparatus according to the first embodiment are employed.

As shown in FIG. 7, the substrate processing method according to this embodiment includes a first substrate processing step S102 where a first substrate process is carried out at a first temperature of the nozzle 21, which is set by controlling the temperature adjusting portion 23, and a second substrate processing step S104 where a second substrate process is carried out at a second temperature of the nozzle 21, which is set by controlling the temperature adjusting portion 23. In this embodiment, the first temperature and the second temperature are different from each other, and the first substrate process and the second substrate process are different from each other.

The substrate processing method according to this embodiment can be carried out, for example, as the following first through fifth methods.

A first method includes a cleaning step where a surface of the substrate is cleaned as the first substrate process and a planarization step where the surface is planarized as the second substrate process. In this method, ethanol is used as the liquid source and Ar is used as the gas source.

Specifically, a cluster beam including a larger amount of the methanol clusters, which is generated by setting a temperature of the nozzle 21 to higher temperatures (e.g., 150° C.), is irradiated onto the surface of the substrate in the cleaning step. Then, a cluster beam including a relatively large amount of the Ar clusters, which is generated by setting a temperature of the nozzle 21 to lower temperatures (e.g., 30° C.), is irradiated onto the cleaned surface of the substrate in the planarization step. With this, the surface of the substrate can be successively cleaned and planarized in the same chamber.

A second method is preferable in order to remove photoresist remaining on a surface of a substrate. In this method, isopropyl alcohol (IPA) is used as the liquid source and Ar or nitrogen (N₂) is used as the gas source.

Specifically, a cluster beam including a larger amount of the IPA clusters, which is generated by setting a temperature of the nozzle 21 to higher temperatures, is irradiated onto the surface of the substrate in the first process step, thereby dissolving the photoresist stuck on the surface of the substrate. Then, a cluster beam including a relatively large amount of the Ar or the nitrogen clusters, which is generated by setting a temperature of the nozzle 21 to lower temperatures, is irradiated onto the surface of the substrate in the second process step, thereby removing photoresist residue that has remained on the surface of the substrate. With this, dissolving the photoresist and removing the photoresist residue can be successively carried out in the same chamber.

A third method is preferable in order to remove etching residue remaining on a surface of a substrate after an etching process. In this method, water (H₂O) is used as the liquid source when the etching is carried out using halogen gases, or IPA is used as the liquid source when the etching is carried out using carbon fluoride series gas, while Ar or nitrogen is used as the gas source.

Specifically, a cluster beam including a relatively large amount of H₂O clusters or IPA clusters, which is generated by setting a temperature of the nozzle 21 to higher temperatures, is irradiated onto the surface of the substrate in the first substrate process, thereby dissolving the etching residue stuck on the surface of the substrate. Then, a cluster beam including a larger amount of Ar clusters or nitrogen clusters, which is generated by setting a temperature of the nozzle 21 to lower temperatures, is irradiated onto the surface of the substrate in the second substrate process, thereby removing the etching residue that has remained on the surface of the substrate. With this, the etching residue can be successively dissolved and removed in the same chamber.

A fourth method is preferable in order to remove a high-k (high dielectric constant) material stuck on a surface of a substrate. In this method, ammonia water (NH₄OH) is used as the liquid source, and hydrogen chloride (HCl) gas is used as the gas source.

Specifically, a cluster beam including a relatively large amount of the ammonia water clusters, which is generated by setting a temperature of the nozzle 21 to higher temperatures, is irradiated onto the surface of the substrate in the first substrate process, thereby reducing the high-k material stuck on the surface of the substrate. Then, a cluster beam including a larger amount of the hydrogen chlorine clusters, which is generated by setting a temperature of the nozzle 21 to lower temperatures, is irradiated onto the surface of the substrate in the second substrate process, thereby vaporizing the high-k material that has still remained on the surface of the substrate. With this, the high-k material stuck on the surface of the substrate can be removed in the same chamber.

A fifth method includes a third substrate process (not shown in FIG. 7) and is preferable in order to remove residue of highly dosed photoresist stuck on a surface of a substrate. In this method, IPA is used as the liquid source, and carbon dioxide (CO₂), Ar, or nitrogen is used as the gas source.

Specifically, a cluster beam including a relatively large amount of the carbon dioxide clusters, which is generated by setting a temperature of the nozzle 21 to lower temperatures, is irradiated onto the surface of the substrate in the first substrate process, thereby breaking a crust layer, which is a surface layer of the highly dosed photoresist stuck on the surface of the substrate. Next, a cluster beam including a larger amount of the IPA clusters, which is generated by setting a temperature of the nozzle 21 to higher temperatures, is irradiated onto the surface of the substrate in the second substrate process, thereby dissolving the photoresist that has still been stuck on the surface of the substrate. Then, a cluster beam including a relatively large amount of the Ar or nitrogen clusters, which is generated by setting a temperature of the nozzle 21 to lower temperatures, is irradiated onto the surface of the substrate in the third substrate process (not shown in FIG. 7), thereby removing the photoresist residue that has still remained on the surface of the substrate.

Incidentally, while the substrate processing method including the two or three process steps have been explained in the above embodiment, the substrate processing method may include four or more process steps that are successively carried out.

While the present invention has been described with reference to the foregoing embodiments, the present invention is not limited to the disclosed embodiments, but may be modified or altered within the scope of the accompanying claims.

What is claimed is:

1. A cluster beam generating method that generates a cluster beam, the cluster beam generating method comprising steps of:
mixing a gas source material and a liquid source material in a mixer;
supplying a cluster beam including clusters originating from the gas source material and clusters originating from the liquid source material that are mixed in the mixer from a nozzle; and
adjusting a temperature of the nozzle using a temperature adjusting portion that adjusts a temperature of the nozzle, thereby controlling a ratio of the clusters originating from the gas source material and the clusters originating from the liquid source material in the cluster beam.

2. The cluster beam generating method of claim 1, wherein a temperature of the nozzle is set in the step of adjusting a temperature of the nozzle so that an average cluster size of the clusters supplied from the nozzle becomes a desired value.

3. The cluster beam generating method of claim 1, further comprising steps of:
preparing a second nozzle that supplies a second cluster beam including clusters originating from the gas source material and clusters originating from the liquid source material that are mixed in the mixer, wherein the second nozzle and the nozzle may be selectively used; and a second temperature adjusting portion that is provided to the second nozzle and adjusts a temperature of the second nozzle to a different temperature from the temperature of the nozzle, thereby controlling a ratio of the clusters originating from the gas source material and the clusters originating from the liquid source material in the second cluster beam; and
selecting and using one of the nozzle and the second nozzle.

4. The cluster beam generating method of claim 1, wherein in the step of adjusting a temperature of the nozzle the temperature adjusting portion is controlled by a temperature controlling portion so that a temperature of the nozzle may be set to one of a first temperature and a second temperature different from the first temperature, wherein a ratio of the clusters originating from the gas source material and the clusters originating from the liquid source material at the first temperature is different from a ratio of the clusters originating from the gas source material and the clusters originating from the liquid source material at the second temperature.

5. The cluster beam generating method of claim 1, wherein an average particle size of the clusters in the cluster beam is in a predetermined range.

6. A substrate processing method comprising a step of irradiating a cluster beam generated by the cluster beam generating method of claim 1 onto a substrate, thereby carrying out a substrate process with respect to the substrate.

7. The substrate processing method of claim 6, wherein the step of irradiating the cluster beam onto the substrate comprises steps of:
irradiating the cluster beam at a first temperature of the nozzle, thereby carrying out a first substrate process; and
irradiating the cluster beam at a second temperature of the nozzle, thereby carrying out a second process, after the first process.

8. The substrate processing method of claim 7, wherein the cluster beam includes a relatively larger amount of one of the clusters originating from the gas source material and the liquid source material than the other one of the clusters originating from the gas source material and the liquid source material at the first temperature, and
wherein the cluster beam includes a relatively larger amount of the other one of the clusters originating from the gas source material and the liquid source material than the one of the clusters originating from the gas source material and the liquid source material at the second temperature.

9. The substrate processing method of claim 6, wherein the substrate process is one or more of cleaning, photoresist removal, planarization of a substrate surface, etching residue removal, and insulating film removal.
